(19) United States
(12) Patent Application Publication
(10) Pub. No.: US 2012/0273036 A1
(43) Pub. Date: Nov. 1, 2012

(54) PHOTOELECTRIC CONVERSION DEVICE AND MANUFACTURING METHOD THEREOF

(75) Inventors: Ryosuke MOTOYOSHI, Hadano (JP); Takashi Hirose, Yokohama (JP); Naoto Kusumoto, Isehara (JP)

(73) Assignee: SEMICONDUCTOR ENERGY LABORATORY CO., LTD., Atsugi-shi (JP)

(21) Appl. No.: 13/448,551

(22) Filed: Apr. 17, 2012

(30) Foreign Application Priority Data
Apr. 29, 2011 (JP) 2011-102573

(51) Int. Cl. H01L 31/0264; H01L 31/0376; H01L 31/18; H01L 31/036

(52) U.S. Cl. 136/255; 136/261; 438/71; 257/E31.032

(57) ABSTRACT

To provide a photoelectric conversion device with less metal contamination and surface detects, and a manufacturing method thereof. The photoelectric conversion device is formed in the following manner: a surface of the single crystal silicon substrate is soaked in an alkaline solution to perform etching so that unevenness including a plurality of minute projections each having a substantially square pyramidal shape and a depression formed between the adjacent projections are formed; then, the single crystal silicon substrate having the unevenness is soaked in a mixed acid solution to perform etching so that at a cross section including a vertex of the projection and dividing each of a surface of the projection and a surface facing the aforementioned surface into two equal parts, the vertex of the projection forms an obtuse angle, and a bottom of the depression has a curved surface.

### BACKGROUND OF THE INVENTION

1. Field of the Invention

The present invention relates to a photoelectric conversion device having an uneven light-receiving surface and a manufacturing method thereof.

2. Description of the Related Art

In a photoelectric conversion device such as a solar cell formed using a crystalline silicon substrate, a structure in which minute unevenness is formed on a light-receiving surface, which is also referred to as a texture structure, is often used. Incident light is reflected in a multiple manner on the surface processed to have unevenness, and travels obliquely in a photoelectric conversion region; thus, the optical path length is increased. In addition, a so-called light trapping effect in which light reflected by a back electrode is totally reflected by the surface can occur. Accordingly, electric characteristics of the photoelectric conversion device can be significantly improved.

As a method for forming such unevenness on a surface of a crystalline silicon substrate, a method in which a single crystal silicon substrate having a (100) plane as an initial surface is anisotropically etched using an alkaline solution so that a (111) plane at which the etching rate is low preferentially appears on the surface to form projections is known. For example, in Non-Patent Document 1, a method is disclosed in which a single crystal silicon substrate is etched with the use of a low-concentration alkaline solution in which several to several tens percent isopropyl alcohol is added to several percent sodium hydroxide solution and which is heated at 70° C. to 90° C.

### REFERENCE

### Non-Patent Document

[Non-Patent Document 1]

D. L. King and M. E. Buck, “Experimental Optimization of an Anisotropic Etching Process for Random Texturization of Silicon Solar Cells,” 22nd IEEE PVSC. 1991, pp. 303-308 (1991).

### SUMMARY OF THE INVENTION

When an etching step using a low-concentration alkaline solution as described above is performed, a metal compound such as a loose grain (a material for grinding used in a slicing step) which remains on a crystalline silicon substrate cannot be removed sufficiently; thus, metal contamination of the surface of the substrate occurs. Accordingly, in order to improve a carrier lifetime, many steps such as performing acid cleaning like RCA cleaning before and after the etching step are required.

Further, an increase in surface defects such as dangling bonds due to an increase in surface area of a single crystal silicon substrate by the formation of unevenness becomes a factor in inhibiting improvement in a carrier lifetime.

Further, there is a case where an effect of a passivation film is not obtained sufficiently since coverage with the passivation film formed over the unevenness is reduced due to the unevenness.

Thus, an object of one embodiment of the present invention is to provide a photoelectric conversion device with less metal contamination and a manufacturing method thereof. Further, an object of one embodiment of the present invention is to provide a photoelectric conversion device with less surface defects and a manufacturing method thereof.

One embodiment of the present invention disclosed in this specification relates to a photoelectric conversion device in which unevenness is formed on a surface of a single crystal silicon substrate by etching using an alkaline solution and a mixed acid solution.

One embodiment of the present invention disclosed in this specification is a photoelectric conversion device including, between a pair of electrodes, a single crystal silicon substrate having one conductivity type; a first region having a conductivity type opposite to that of the single crystal silicon substrate and provided on one surface of the single crystal silicon substrate; an insulating film provided on the first region; and a second region having the same conductivity type as the single crystal silicon substrate, having higher carrier density than the single crystal silicon substrate, and provided on the other surface of the single crystal silicon substrate. A surface of the single crystal silicon substrate has unevenness including a plurality of minute projections each having a substantially square pyramidal shape and a depression formed between the adjacent projections. At a cross section dividing each of a first side surface of the projection and a second side surface facing the first side surface into two equal parts through a vertex of the projection, the vertex of the projection forms an obtuse angle, and a bottom of the depression has a curved surface.

It is to be noted that the ordinal numbers such as “first” and “second” in this specification, etc. are assigned in order to avoid confusion among components, and do not intended to limit the number or order of the components.

One embodiment of the present invention disclosed in this specification is a photoelectric conversion device including, between a pair of electrodes, a single crystal silicon substrate having one conductivity type; a first silicon semiconductor layer being in contact with one surface of the single crystal silicon substrate; a second silicon semiconductor layer being in contact with the first silicon semiconductor layer and having a conductivity type opposite to that of the single crystal silicon substrate; a third silicon semiconductor layer being in contact with the other surface of the single crystal silicon substrate; and a fourth silicon semiconductor layer being in contact with the third silicon semiconductor layer, having the same conductivity type as the single crystal silicon substrate, and having higher carrier density than the single crystal silicon substrate. A surface of the single crystal silicon substrate has unevenness including a plurality of minute projections each having a substantially square pyramidal shape and a depression formed between the adjacent projections. At a cross section dividing each of a first side surface of the projection and a second side surface facing the first side surface into two equal parts through a vertex of the projection, the vertex of the projection forms an obtuse angle, and a bottom of the depression has a curved surface.

It is preferable that the first silicon semiconductor layer and the third silicon semiconductor layer be each an amorphous silicon layer having i-type conductivity.

Further, it is preferable that the second silicon semiconductor layer and the fourth silicon semiconductor layer be each an amorphous silicon layer or a microcrystalline silicon layer.

One embodiment of the present invention disclosed in this specification is a photoelectric conversion device including a single crystal silicon substrate having one conductivity type; a first insulating layer provided on one surface of the single crystal silicon substrate; a first region having a conductivity type opposite to that of the single crystal silicon substrate and a second region having the same conductivity type as the single crystal silicon substrate and having higher carrier density than the single crystal silicon substrate, which are provided on the other surface of the single crystal silicon substrate; a second insulating layer provided on the other surface of the single crystal silicon substrate; a first electrode being in contact with the first region and provided on the second insulating layer; and a second electrode being in contact with the second region and provided on the second insulating layer. A surface of the single crystal silicon substrate has unevenness including a plurality of minute projections each having a substantially square pyramidal shape and a depression formed between the adjacent projections. At a cross section dividing each of a first side surface of the projection and a second side surface facing the first side surface into two equal parts through a vertex of the projection, the vertex of the projection forms an obtuse angle, and a bottom of the depression has a curved surface.

One embodiment of the present invention disclosed in this specification is a method for manufacturing a photoelectric conversion device, which includes the following steps. A surface of a single crystal silicon substrate having a (100) plane as the surface is soaked in an alkaline solution to perform etching so that unevenness including a plurality of minute projections each having a substantially square pyramidal shape and a depression formed between the adjacent projections are formed; then, the single crystal silicon substrate having the unevenness is soaked in a mixed acid solution to perform etching so that at a cross section dividing each of a first side surface of the projection and a second side surface facing the first side surface into two equal parts, the vertex of the projection forms an obtuse angle, and a bottom of the depression has a curved surface.

As the alkaline solution, a solution containing potassium hydroxide or sodium hydroxide is preferably used.

Further, the mixed acid solution preferably contains hydrofluoric acid, nitric acid, and acetic acid.

According to one embodiment of the present invention, surface area can be decreased to the extent that an effect of unevenness formed on the surface of the single crystal silicon substrate can be maintained, so that the absolute amount of surface defects can be reduced. Further, by the etching using the mixed acid solution, the vertex angle of a cross section of the projection can be an obtuse angle, and further, the bottom of the depression is curved. Thus, coverage with a layer covering the surface of the single crystal silicon substrate having the unevenness can be improved. Furthermore, contaminants such as a metal compound can be removed with the mixed acid solution; thus, metal contamination can be suppressed without increasing the number of steps. By the above one or more effects, electric characteristics of the photoelectric conversion device can be improved.

### BRIEF DESCRIPTION OF THE DRAWINGS

FIG. 1 is a flow chart showing a processing method for forming unevenness on a single crystal silicon substrate.

FIGS. 2A and 2B are STEM photographs of cross sections of a portion provided with unevenness.

FIGS. 3A and 3B are STEM photographs of cross sections of a portion provided with unevenness.

FIGS. 4A and 4B are STEM photographs of cross sections of a portion provided with unevenness.

FIGS. 5A and 5B are cross-sectional views each showing a photoelectric conversion device.

FIGS. 6A to 6C are cross-sectional views showing a method for manufacturing a photoelectric conversion device.

FIGS. 7A to 7C are cross-sectional views showing a method for manufacturing a photoelectric conversion device.

FIGS. 8A and 8B are cross-sectional views each showing a photoelectric conversion device.

FIGS. 9A to 9C are cross-sectional views showing a method for manufacturing a photoelectric conversion device.

FIGS. 10A to 10C are cross-sectional views showing a method for manufacturing a photoelectric conversion device.

FIGS. 11A and 11B are cross-sectional views each showing a photoelectric conversion device.

FIGS. 12A to 12C are cross-sectional views showing a method for manufacturing a photoelectric conversion device.

FIGS. 13A to 13C are cross-sectional views showing a method for manufacturing a photoelectric conversion device.

FIG. 14 is a graph showing reflectance of single crystal silicon substrates processed to have unevenness.

FIG. 15 is a graph showing carrier lifetimes of single crystal silicon substrates processed to have unevenness.

FIGS. 16A to 16D show electric characteristics of photoelectric conversion devices each formed using a single crystal silicon substrate processed to have unevenness.

FIG. 17 is a schematic top view of projections each having a substantially square pyramidal shape provided for a single crystal silicon substrate, which gives a definition of a cross section.

### DETAILED DESCRIPTION OF THE INVENTION

Hereinafter, embodiments of the present invention will be described in detail with reference to the accompanying drawings. However, the present invention is not limited to the description below, and it is easily understood by those skilled in the art that modes and details disclosed herein can be modified in various ways without departing from the spirit and the scope of the present invention. Therefore, the present invention is not construed as being limited to description of the embodiments. Note that in all drawings used to illustrate the embodiments, portions that are identical or portions having similar functions are denoted by the same reference numerals, and their repetitive description may be omitted.

### Embodiment 1

In this embodiment, a processing method for forming unevenness on a single crystal silicon substrate used for a photoelectric conversion device of one embodiment of the present invention is described.

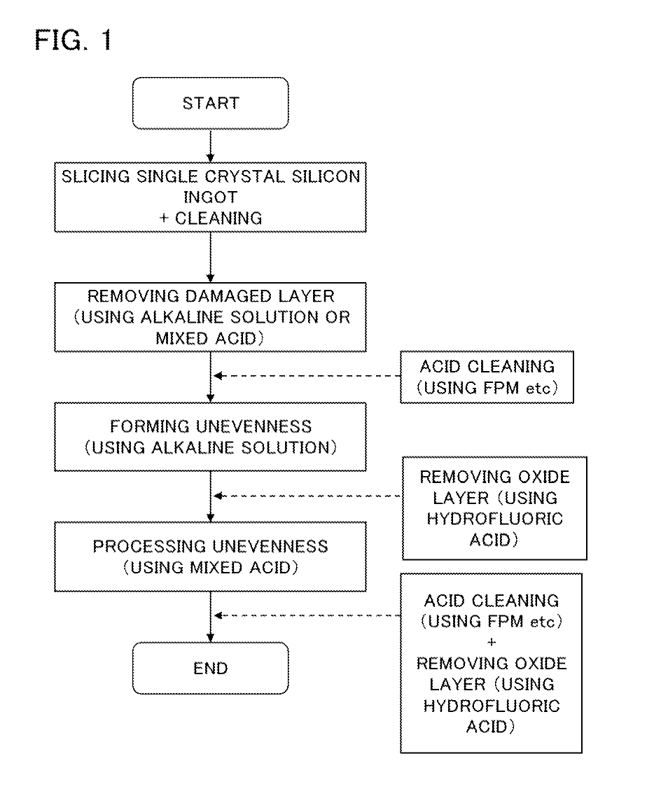

FIG. 1 is a flow chart showing the processing method for forming unevenness on a single crystal silicon substrate used for a photoelectric conversion device of one embodiment of the present invention.

First, a single crystal silicon ingot is sliced with a wire saw or the like to form a substrate. The conductivity type of the single crystal silicon ingot and a type of an impurity for imparting the conductivity type are not limited and can be determined by the practitioner in accordance with its purpose. A single crystal silicon ingot with which plane orientation of a surface (a surface obtained by slicing the single crystal silicon ingot) of a single crystal silicon substrate is a (100) plane is used because in one embodiment of the present invention, unevenness is formed on the surface of the single crystal silicon substrate by utilizing the fact that the etching rate of a (111) plane of crystalline silicon using an alkaline solution is lower than that of the (100) plane of the crystalline silicon.

Subsequently, the sliced single crystal silicon substrate is cleaned. In addition to silicon particles produced by slicing, powder of a material constituting the wire saw or the loose grain is attached to the single crystal silicon substrate. In order to remove these, any one of ultrasonic cleaning, swing cleaning, shower cleaning, and brush cleaning, or a combination of any of these is performed. Further, the cleaning can be performed using water or a commercial organic alkaline cleaner.

Next, a damaged layer is removed. In the vicinity of the surface of the single crystal silicon substrate which has cut with a wire saw or the like, there is a region where performance as a semiconductor is drastically lowered by crystal defects due to mechanical damage or contamination due to contact with an impurity substance. Such a region is referred to as the damaged layer, and a region at a depth of 10 μm to 20 μm from the surface of the single crystal silicon substrate is removed. For an etchant, an alkaline solution with a relatively high concentration, for example, 10% to 50% sodium hydroxide solution, or 10% to 50% pottasium hydroxide solution can be used. Alternatively, a mixed acid in which hydrofluoric acid and nitric acid are mixed, or the mixed acid to which acetic acid is further added may be used.

Next, acid cleaning may be performed. Since many impurities such as a metal component are included in the etchant used when the damaged layer is removed, the impurities may be attached to the surface of the single crystal silicon substrate after the damaged layer is removed. The acid cleaning is effective for removing such impurities. As an acid, for example, a mixture (FPM) of 0.5% hydrofluoric acid and 1% hydrogen peroxide, or the like can be used. Alternatively, RCA cleaning or the like may be performed.

Next, unevenness is formed on the surface of the single crystal silicon substrate. The unevenness is formed utilizing a difference in etching rates among plane orientations in etching of the crystalline silicon using the alkaline solution. For an etchant, an alkaline solution with a relatively low concentration, for example, 1% to 5% sodium hydroxide solution, or 1% to 5% potassium hydroxide solution can be used, preferably several percent isopropyl alcohol is added thereto. The temperature of the etchant is 70° C. to 90° C., and the single crystal silicon substrate is soaked in the etchant for 30 to 60 minutes. By this treatment, unevenness including a plurality of minute projections each having a substantially square pyramidal shape and a depression formed between adjacent projections can be formed.

Next, a step for removing an oxide layer may be performed. In the etching step for forming the unevenness, the oxide layer is non-uniformly formed on a surface of the single crystal silicon substrate; thus, the oxide layer is preferably removed so that the next step is performed stably. Another purpose to remove the oxide layer is to remove a component of the alkaline solution, which is likely to remain in the oxide layer. When an alkali metal ion, e.g., an Na ion or a K ion enters the single crystal silicon substrate, a lifetime is decreased, and the electric characteristics of the photoelectric conversion device is drastically lowered. Note that in order to remove the oxide layer, 1 to 5 percent diluted hydrofluoric acid may be used.

Next, the unevenness formed on the surface of the single crystal silicon substrate is processed. This processing is performed using a mixed acid in which hydrofluoric acid and nitric acid are mixed, or using the mixed acid to which acetic acid is further added. By adding the acetic acid, an effect of keeping oxidizing power of nitric acid to stably perform etching, and an effect of adjusting an etching rate can be obtained. For example, it is preferable that a volume ratio of hydrofluoric acid, nitride acid and acetic acid be 1:1.5 to 3:2 to 4. Note that in this specification, the mixed acid solution containing hydrofluoric acid, nitride acid, and acetic acid is referred to as HF-nitric-acetic acid.

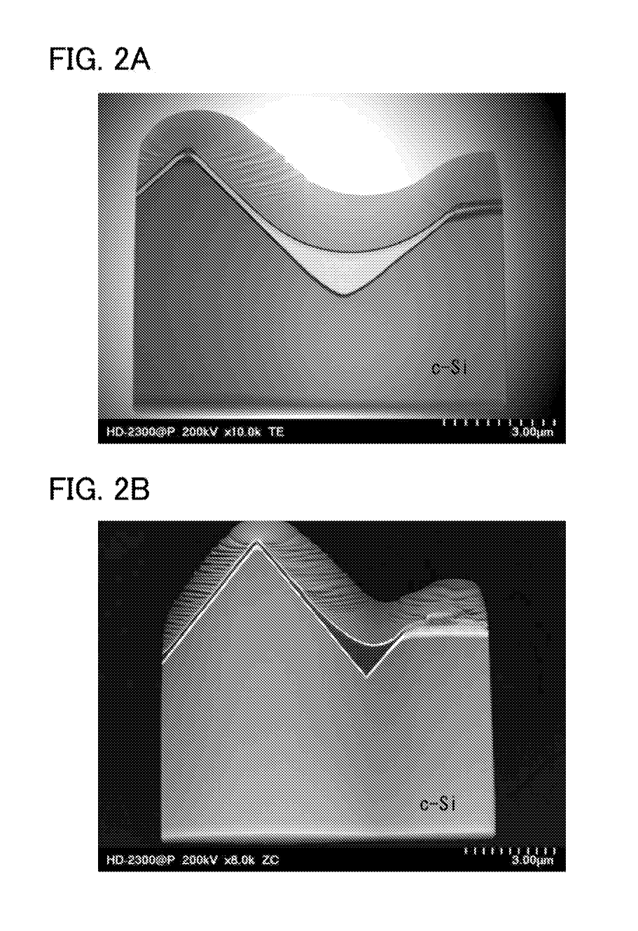

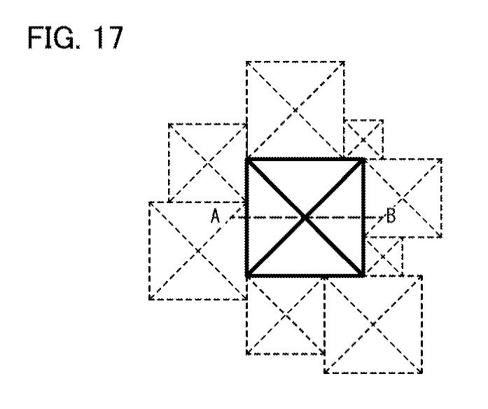

FIG. 2A is a STEM photograph of a cross section of a sample in which unevenness formed on the surface of the single crystal silicon substrate is etched at depth of 3.5 μm in the thickness direction from the surface using HF-nitric-acetic acid (hydrofluoric acid:nitride acid:acetic acid=1:2:3). Further, FIG. 2B is a STEM photograph of a cross section of a sample on which the etching using HF-nitric-acetic acid is not performed. In each of the STEM photographs, the cross section including a vertex of a minute projection having a substantially square pyramidal shape and dividing each of a surface of the projection and a surface facing the aforementioned surface into two equal parts is observed. The cross section corresponds to a cross section along line A-B in a schematic top view of the projection having a substantially square pyramidal shape in the single crystal silicon substrate, which is shown in FIG. 17. Further, in the single crystal silicon substrate having a (100) plane as the initial surface, a (110) plane including a vertex of a projection can also be referred to as the cross section.

When FIG. 2A is compared with FIG. 2B, it can be observed that the vertex angle of the projection in FIG. 2A is larger than that in FIG. 2B and the bottom of the depression is processed to be curved in FIG. 2A. In each of the samples, i-type amorphous silicon, p-type amorphous silicon, and indium tin oxide (ITO) are stacked in this order over the single crystal silicon substrate having unevenness, and a carbon film, a platinum film, a resin film, and the like are stacked thereover for observation with STEM.

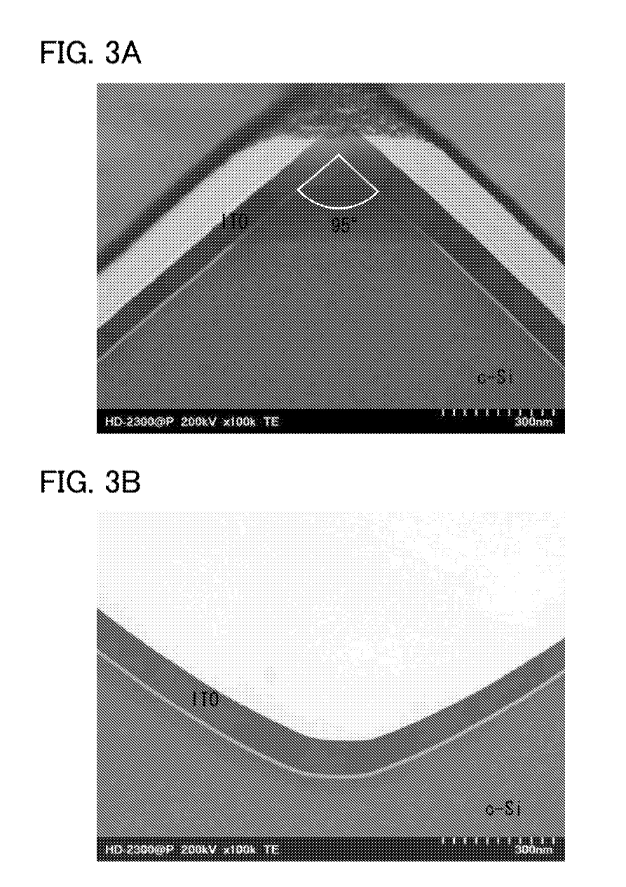

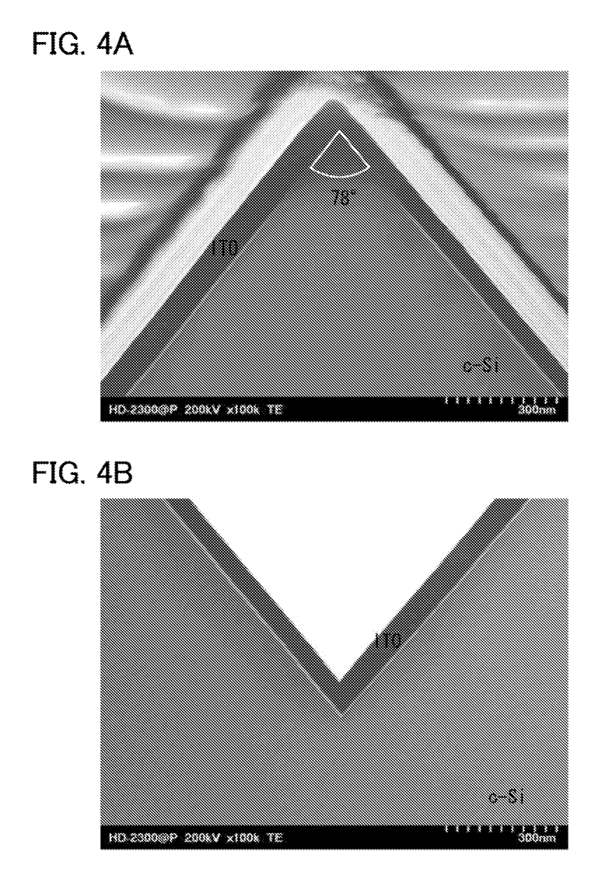

FIGS. 3A and 3B show enlarged photographs of the projection and depression of FIG. 2A. Further, FIGS. 4A and 4B show enlarged photographs of the projection and depression of FIG. 2B. Specifically, the vertex angle of the projection before the etching using HF-nitric-acetic acid is about 78° (an acute angle); on the other hand, the vertex angle of the depression after the etching is about 95° (an obtuse angle). Further, the depression before the etching has a V-shape; on the other hand, the bottom of the depression after the etching has a curved surface. Thus, coverage with a passivation film and the like which are formed over the unevenness is improved, and a carrier lifetime can be improved.

Furthermore, the height of the projection is reduced by the etching, so that the vertex angle of the projection becomes an obtuse angle and the surface area of the whole substrate is reduced. Thus, the absolute amount of surface defects such as dangling bonds can be reduced, and the carrier lifetime of the single crystal substrate can be improved.

As described above, in order to improve coverage with the passivation film and reduce the absolute amount of surface defects so that electric characteristics of the photoelectric conversion device are improved, the vertex angle of the projection is preferably greater than 90° and less than or equal to 120°, further preferably greater than 90° and less than or equal to 100°. This is because the coverage is not improved when the vertex angle is less than 90°, and an optical effect (an increase in optical path length) and the like are sharply decreased when the vertex angle is larger than 120°.

Next, the step of acid cleaning with the use of FPM and the like and the removal step of an oxide layer using diluted hydrofluoric acid which are described above may be performed. By these steps, metal components (including an alkaline metal) that are impurities can be removed completely. Note that these steps can be omitted because impurities such as metal components are removed by the etching of the single crystal silicon substrate surface using HF-nitric-acetic acid in the previous step. That is, the etching of the single crystal silicon substrate surface using HF-nitric-acetic acid in one embodiment of the present invention is accompanied by the effect of removing impunities; thus, the steps for the purpose of removing impurities and the oxide layer which are described in this embodiment can be all omitted. Accordingly, the unevenness can be formed on the single crystal substrate while metal contamination can be suppressed with a small number of steps.

This embodiment can be freely combined with any of the other embodiments and an example.

### Embodiment 2

In this embodiment, a photoelectric conversion device which can be formed using the single crystal silicon substrate having unevenness and described in Embodiment 1, and a manufacturing method thereof are described.

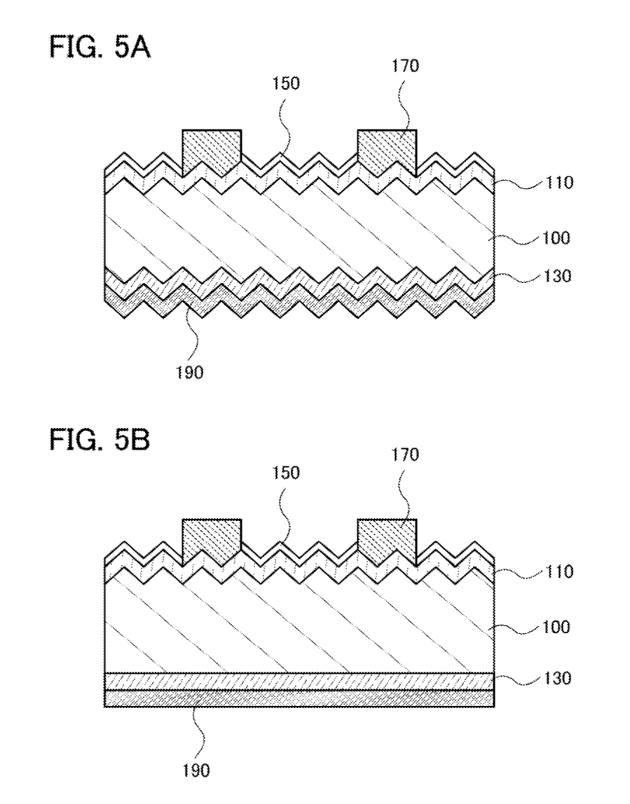

The photoelectric conversion devices shown in FIGS. 5A and 5B each include a single crystal silicon substrate 100 whose surface has unevenness, a first region 110 formed on one surface of the single crystal silicon substrate 100, a second region 130 formed on the other surface of the single crystal silicon substrate 100, an insulating layer 150 formed on the first region 110, a first electrode 170 being in contact with the first region 110, and a second electrode 190 being in contact with the second region 130. Note that the first electrode 170 is a grid electrode, and a surface on the first electrode 170 side serves as a light-receiving surface.

In FIG. 5A, both surfaces of the single crystal silicon substrate 100 have unevenness, which can be formed in such a manner that both the surfaces of the single crystal silicon substrate 100 are subjected to etching without using masks in the etching for forming unevenness. In FIG. 5B, only one surface of the single crystal silicon substrate 100 has unevenness, which can be formed in such a manner that the other surface of the single crystal silicon substrate 100 is covered with a mask in the etching for forming unevenness and only the one surface is subjected to etching. It is possible to refer to the method described in Embodiment in 1 for the etching for forming the unevenness.

Incident light is reflected in a multiple manner on the surface processed to have unevenness, and travels obliquely in the single crystal silicon substrate; thus, the optical path length is increased. In addition, a so-called light trapping effect in which light reflected by a back electrode is totally reflected by the surface can occur.

The single crystal silicon substrate 100 has one conductivity type, and the first region 110 is a region having a conductivity type opposite to that of the single crystal silicon substrate 100. Thus, a p-n junction is formed at the interface between the single crystal silicon substrate 100 and the first region 110.

The second region 130 is a back surface field (BSF) layer, which has the same conductivity type as the single crystal silicon substrate 100 and has higher carrier density than the single crystal silicon substrate 100. When the BSF layer is formed, an n-n⁺ junction or a p-p⁺ junction is formed, and minority carriers are repelled by the electric field of the n-n⁺ junction or the p-p⁺ junction and attracted to the p-n junction side, whereby recombination of carriers in the vicinity of the second electrode 190 can he prevented.

The second region 130 can be easily formed by diffusing impurities contained in the second electrode 190. For example, when the single crystal silicon substrate 100 has p-type conductivity, an aluminum film or an aluminum paste is formed as the second electrode 190, and thermal diffusion of aluminum which is an impurity imparting p-type conductivity is performed, whereby the second region 130 can be formed.

Further, over the first region 110, the insulating layer 150 having a light-transmitting property is preferably provided in a portion except a junction between the first region 110 and the first electrode 170. Provision of the insulating layer 150 has a protection effect, an antireflection effect, and an effect of reducing surface defects on the first region 110. As the insulating layer 150 having a light-transmitting property, a silicon oxide film or a silicon nitride film formed by a plasma CVD method or a sputtering method can be used.

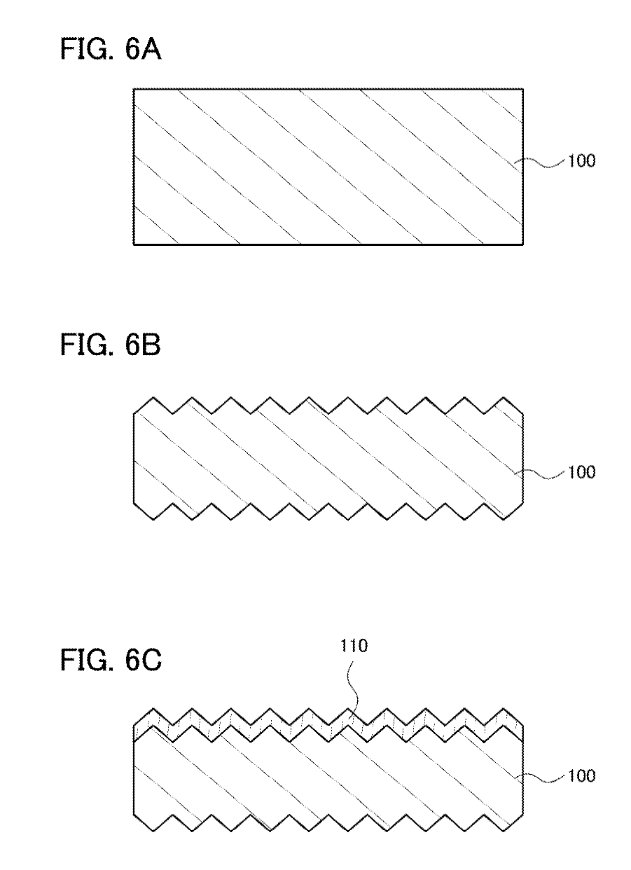

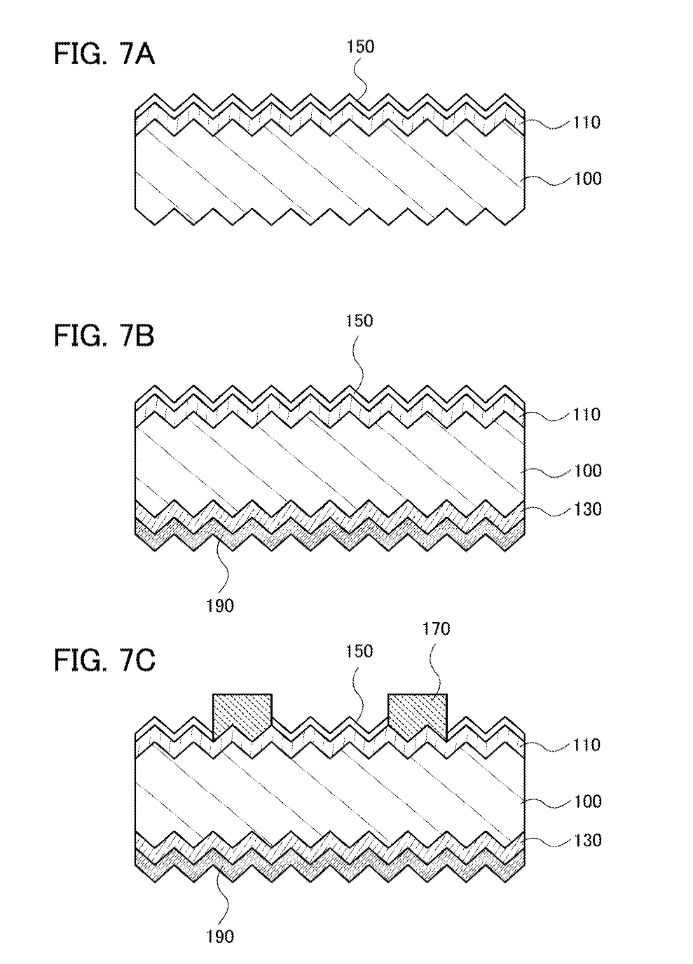

Next, a method for manufacturing the photoelectric conversion device, which is shown in FIG. 1, is described with reference to FIGS. 6A to 6C and FIGS. 7A to 7C.

As the single crystal silicon substrate 100 used in one embodiment of the present invention, a single crystal silicon substrate having a (100) plane as a surface is used (see FIG. 6A). The conductivity type and the manufacturing method of the single crystal silicon substrate are not limited and can be determined by the practitioner as appropriate. In this embodiment, an example in which a p-type single crystal silicon substrate is used as the single crystal silicon substrate 100 is described.

Next, the surface and the back surface of the single crystal silicon substrate 100 are processed to have unevenness (see FIG. 6B). Embodiment 1 can be referred to for the processing method for forming the unevenness.

Here, the conductivity type of the single crystal silicon substrate 100 is p-type; thus, impurities imparting n-type conductivity are diffused into a surface layer of the single silicon substrate 100, so that the first region 110 is formed (see FIG. 6C). As impurities imparting n-type conductivity, phosphorus, arsenic, antimony, and the like can be given. For example, the single crystal silicon substrate 100 is subjected to heat treatment at a temperature higher than or equal to 800° C. and lower than or equal to 900° C. in an atmosphere of phosphorus oxychloride, whereby phosphorus can be diffused at a depth of approximately 0.5 μm from the surface of the single crystal silicon substrate 100. The first region 110 can be formed on the one surface of the single crystal silicon substrate 100 with a mask formed on the other surface of the single crystal silicon substrate by an existing method. Alternatively, the first region 110 can be formed on the one surface of the single crystal silicon substrate 100 in such a manner that after forming diffusion layers on both the surfaces of the single crystal substrate, the diffusion layer on the other surface of single crystal silicon substrate is etched by an existing method.

Next, the insulating layer 150 having a light-transmitting property is formed over the first region 110 (see FIG. 7A). A silicon oxide film or a silicon nitride film with a thickness of greater than or equal to 50 nm and less than or equal to 100 nm, which is formed by a plasma CVD method or a sputtering method, can be used as the insulating layer 150. In this embodiment, a silicon nitride film with a thickness of 50 nm formed by a plasma CVD method is used as the insulating layer 150.

Next, the second region 130 and the second electrode 190 are formed (see FIG. 7B). In this embodiment, the conductivity type of the single crystal silicon substrate 100 is p-type; thus, a conductive layer including impurities imparting p-type conductivity is formed on the other surface of the single crystal silicon substrate 100, and the impurities are diffused to form a layer with a high carrier concentration, so that p-p⁺ junction is formed. The second region 130 and the second electrode 190 can be formed, for example, in the following manner: an aluminum paste is applied to the other surface of the single crystal silicon substrate 100 and baking is performed to thermally diffuse aluminum into the surface layer of the other surface of the single crystal silicon substrate 100.

Next, by a screen printing method, a conductive resin to be the first electrode 170 is applied on the insulating layer 150. Note that the conductive resin used here may be a silver paste, a copper paste, a nickel paste, a molybdenum paste, or the like. Further, the first electrode 170 may be a stacked layer of different materials, such as a stacked layer of a silver paste and a copper paste.

Next, the conductive resin is baked, so that the first region 110 is in contact with the first electrode 170 (see FIG. 7C). The conductive resin is not in contact with the first region 110 at the aforementioned stage where the conductive resin is applied because the insulating layer 150 is provided therebetween. However, the conductor component of the conductive resin can penetrate the insulating layer 150 and be in contact with the first region 110 by baking the conductive resin.

As described above, according to one embodiment of the present invention, a photoelectric conversion device having excellent electric characteristics can be formed.

This embodiment can be freely combined with any of the other embodiments and an example.

### Embodiment 3

In this embodiment, a photoelectric conversion device which has a different structure from the photoelectric conversion device described in Embodiment 2 and a manufacturing method thereof are described.

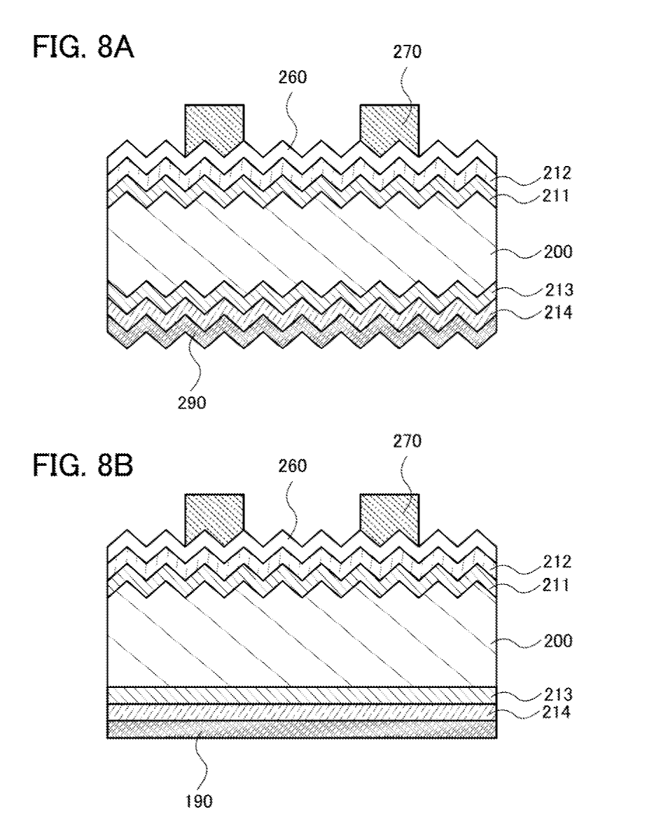

In each of the photoelectric conversion devices shown in FIGS. 8A and 8B, a first silicon semiconductor layer 211, a second silicon semiconductor layer 212, a light-transmitting conductive film 260, and a first electrode 270 are stacked in this order on one surface of a single crystal silicon substrate 200, and a third silicon semiconductor layer 213, a fourth silicon semiconductor layer 214, and a second electrode 290 are stacked in this order on the other surface of the single crystal silicon substrate 200. Note that the first electrode 270 is a grid electrode, and the surface on which the first electrode 270 is formed serves as a light-receiving surface. In addition, the second electrode 290 may be a grid electrode, and both surfaces of the single crystal silicon substrate 200 may serve as light-receiving surfaces. In that case, a light-transmitting conductive film is preferably provided between the fourth silicon semiconductor layer 214 and the second electrode 290.

In FIG. 8A, both the surfaces of the single crystal silicon substrate 200 have unevenness, which can be formed in such a manner that both the surfaces of the single crystal silicon substrate are subjected to etching without using masks in the etching for forming unevenness. In FIG. 8B, only one surface of the single crystal silicon substrate 200 has unevenness, which can be formed in such a manner that the other surface of the single crystal silicon substrate 200 is covered with a mask in the etching for forming unevenness and only the one surface is subjected to etching. It is possible to refer to the method described in Embodiment in 1 for the etching for forming the unevenness.

Incident light is reflected in a multiple manner on the surface processed to have unevenness, and travels obliquely in the single crystal silicon substrate; thus, the optical path length is increased. In addition, a so-called light trapping effect in which light reflected by a back electrode is totally reflected by the surface can occur.

In this embodiment, the first silicon semiconductor layer 211 and the third silicon semiconductor layer 213 are high-quality i-type semiconductor layers with less defects and surface defects on the single crystal silicon substrate 200 can be terminated. Note that in this specification, an “i-type semiconductor” refers not only to a so-called intrinsic semiconductor in which the Fermi level lies in the middle of the band gap, but also to a semiconductor in which the concentration of each of an impurity imparting p-type conductivity and an impurity imparting n-type conductivity is 1×10²⁰ cm⁻³ or less, and in which the photoconductivity is 100 times or more as high as the dark conductivity. This i-type silicon semiconductor may include an element belonging to Group 13 or Group 15 of the periodic table as an impurity.

The single crystal silicon substrate 200 has one conductivity type, and the second silicon semiconductor layer 212 is a semiconductor layer having a conductivity type opposite to that of the single crystal silicon substrate 200. Thus, a p-n junction is formed between the single crystal silicon substrate 200 and the second silicon semiconductor layer 212 with the first silicon semiconductor layer 211 provided therebetween.

The fourth silicon semiconductor layer 214 has the same conductivity type as the single crystal silicon substrate 200 and has higher carrier density than the single crystal silicon substrate 200. A p-p⁺ junction or an n-n⁺ junction is formed between the single crystal silicon substrate 200 and the fourth silicon semiconductor layer 214 with the third silicon semiconductor layer 213 provided therebetween. That is, the fourth silicon semiconductor layer 214 functions as a BSF layer.

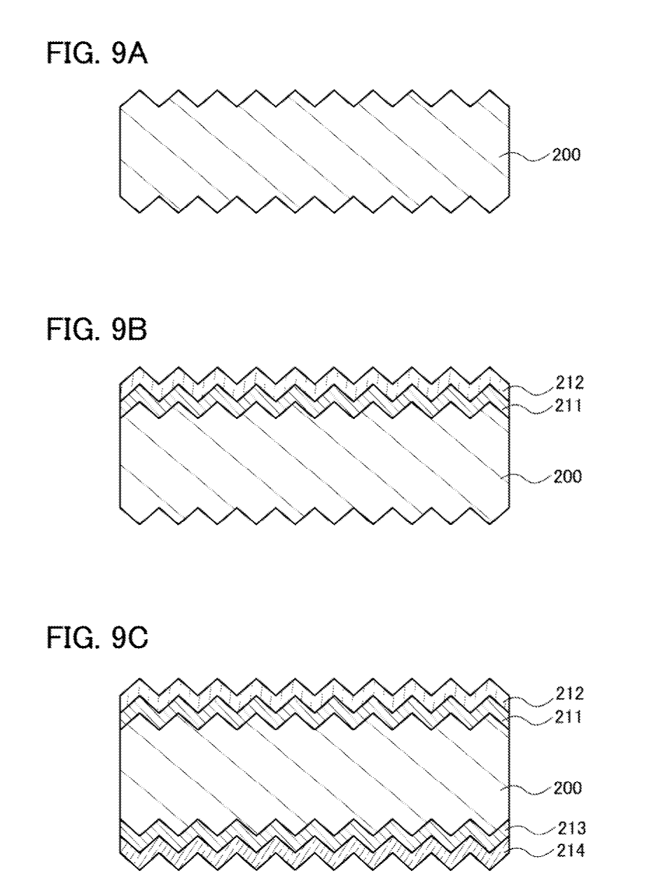

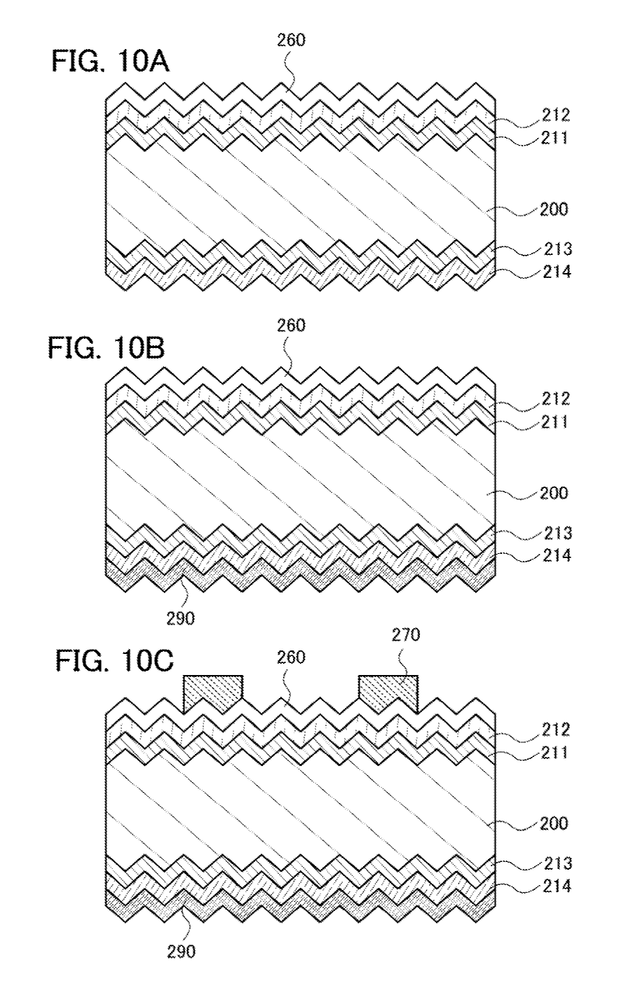

Next, a method for manufacturing the photoelectric conversion device shown in FIG. 8A is described with reference to FIGS. 9A to 9C and FIGS. 10A to 10C.

As the single crystal silicon substrate 200 used in one embodiment of the present invention, a single crystal silicon substrate having a (100) plane as a surface is used. The conductivity type and the manufacturing method of the single crystal silicon substrate are not limited and can be determined by the practitioner as appropriate. In this embodiment, an example in which an n-type single crystal silicon substrate is used as the single crystal silicon substrate 200 is described.

Next, the surface and the back surface of the single crystal silicon substrate 200 are processed to have unevenness. Embodiment 1 can be referred to for the processing method for forming the unevenness (see FIG. 9A).

Next, the first silicon semiconductor layer 211 is formed on the one surface of the single crystal silicon substrate 200 by a plasma CVD method. The first silicon semiconductor layer 211 preferably has a thickness of greater than or equal to 3 nm and less than or equal to 50 nm. In this embodiment, the first silicon semiconductor layer 211 is i-type amorphous silicon, which has a film thickness of 5 nm.

The deposition conditions of the first silicon semiconductor layer 211 are as follows: monosilane is introduced to a reaction chamber at a flow rate of greater than or equal to 5 sccm and less than or equal to 200 sccm; the pressure inside the reaction chamber is higher than or equal to 10 Pa and lower than or equal to 100 Pa; the electrode interval is greater than or equal to 15 mm and less than or equal to 40 mm; and the power density is greater than or equal to 8 mW/cm² and less than or equal to 50 mW/cm².

Next, the second silicon semiconductor layer 212 is formed on the first silicon semiconductor layer 211 (see FIG. 9B). The thickness of the second silicon semiconductor layer 212 is preferably greater than or equal to 3 nm and less than or equal to 50 nm. In this embodiment, the second silicon semiconductor layer 212 is p-type microcrystalline silicon, which has a film thickness of 10 nm.

The deposition conditions of the second silicon semiconductor layer 212 are as follows: monosilane, hydrogen, and a hydrogen-based diborane (0.1%) are introduced into a reaction chamber respectively at a flow rate of greater than or equal to 1 sccm and less than or equal to 10 sccm, a flow rate of greater than or equal to 100 sccm and less than or equal to 5000 sccm, and a flow rate of greater than or equal to 5 sccm and less than or equal to 50 sccm; the pressure inside the reaction chamber is higher than or equal to 450 Pa and lower than or equal to 100000 Pa, preferably higher than or equal to 2000 Pa and lower than or equal to 50000 Pa; the electrode interval is greater than or equal to 8 mm and less than or equal to 30 mm, and the power density is greater than or equal to 200 mW/cm² and less than or equal to 1500 mW/cm².

Next, the third silicon semiconductor layer 213 is formed on the other surface of the single crystal silicon substrate 200 by a plasma CVD method. The third silicon semiconductor layer 213 preferably has a thickness of greater than or equal to 3 nm and less than or equal to 50 nm. In this embodiment, the third silicon semiconductor layer 213 is i-type amorphous silicon, which has a film thickness of 5 nm. It is to be noted that the third silicon semiconductor layer 213 can be formed under the same deposition conditions as in the case of the first silicon semiconductor layer 211.

Next, the fourth silicon semiconductor layer 214 is formed on the third silicon semiconductor layer 213 (see FIG. 9C). The thickness of the fourth silicon semiconductor layer 214 is preferably greater than or equal to 3 nm and less than or equal to 50 nm. In this embodiment, the fourth silicon semiconductor layer 214 is n-type microcrystalline silicon and has a thickness of 10 nm.

The deposition conditions of the fourth silicon semiconductor layer 214 are as follows: monosilane gas, hydrogen, and a hydrogen-based phosphine (0.5%) are introduced into a reaction chamber respectively at a flow rate of greater than or equal to 1 sccm and less than or equal to 10 sccm, a flow rate of greater than or equal to 100 sccm and less than or equal to 5000 sccm, and a flow rate of greater than or equal to 5 sccm and less than or equal to 50 sccm; the pressure inside the reaction chamber is higher than or equal to 450 Pa and lower than or equal to 100000 Pa, preferably higher than or equal to 2000 Pa and lower than or equal to 50000 Pa; the electrode interval is greater than or equal to 8 mm and less than or equal to 30 mm, and the power density is greater than or equal to 200 mW/cm² and less than or equal to 1500 mW/cm².

Note that in this embodiment, although an RF power source with a frequency of 13.56 MHz is used as a power source in forming the silicon semiconductor layers, an RF power source with a frequency of 27.12 MHz, 60 MHz, or 100 MHz may be used instead. Furthermore, film deposition may be performed by pulsed discharge as well as with continuous discharge. The implementation of pulse discharge can improve the film quality and reduce particles produced in the gas phase.

Next, the light-transmitting conductive film 260 is formed over the second silicon semiconductor layer 212 (see FIG. 10A). For the light-transmitting conductive film 260, the following can be used: indium tin oxide; indium tin oxide containing silicon; indium oxide containing zinc; zinc oxide; zinc oxide containing gallium; zinc oxide containing aluminum; tin oxide; tin oxide containing fluorine; tin oxide containing antimony; graphene, or the like. The light-transmitting conductive film 260 is not limited to a single layer, and may be a stacked layer of different films. For example, a stacked layer of an indium tin oxide and a zinc oxide containing aluminum, a stacked layer of an indium tin oxide and a tin oxide containing fluorine, etc. can be used. A total film thickness is 10 nm or more and 1000 nm or less.

Next, the second electrode 290 is formed on the fourth silicon semiconductor layer 214 (see FIG. 10B). The second electrode 290 can be formed using a low-resistance metal such as silver, aluminum, or copper by a sputtering method, a vacuum evaporation method, or the like. Alternatively, the second electrode 290 may be formed using a conductive resin such as a silver paste or a copper paste by a screen printing method.

Note that the formation order of the films provided on the surface and the back surface of the single crystal silicon substrate 200 is not limited to the order described above as long as the structure shown in FIG. 10B can be obtained. For example, the first silicon semiconductor layer 211 may be formed, and then the third silicon semiconductor layer 213 may be formed.

Next, by a screen printing method, a conductive resin is applied on the light-transmitting conductive film 260 and is baked, so that the first electrode 270 is formed. Note that the conductive resin used here may be a silver paste, a copper paste, a nickel paste, a molybdenum paste, or the like. Further, the first electrode 270 may be a stacked layer of different materials, such as a stacked layer of a silver paste and a copper paste.

As described above, according to one embodiment of the present invention, a photoelectric conversion device having excellent electric characteristics can be formed.

This embodiment can be freely combined with any of the other embodiments and an example.

### Embodiment 4

In this embodiment, a photoelectric conversion device which has a different structure from the photoelectric conversion devices described in Embodiments 1 and 2, and a manufacturing method thereof are described.

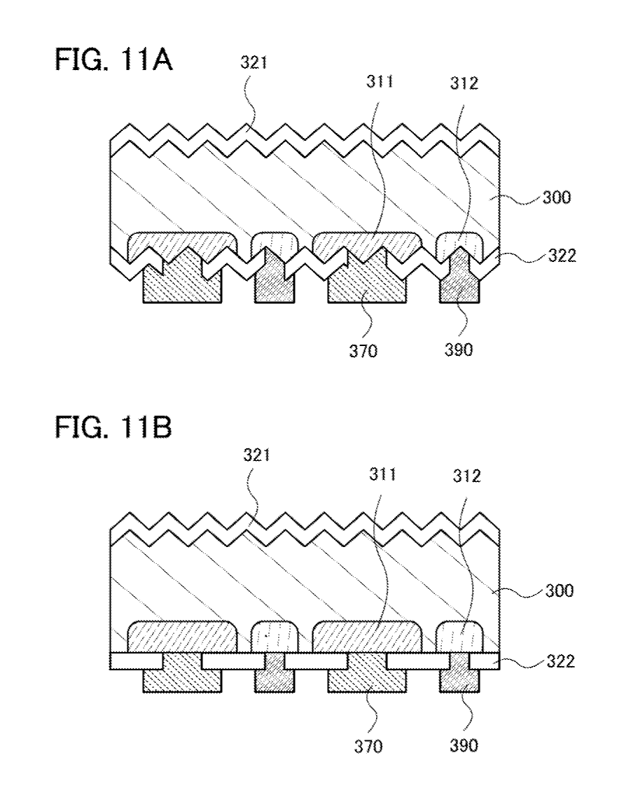

The photoelectric conversion devices shown in FIGS. 11A and 11B each include a single crystal silicon substrate 300 whose surface has unevenness, a first insulating layer 321 formed on one surface of the single crystal silicon substrate 300, a first region 311 and a second region 312 which are formed in the other surface of the single crystal silicon substrate 300, a second insulating layer 322 formed on the other surface of the single crystal silicon substrate 300, a first electrode 370 being in contact with the first region 311, and a second electrode 390 being in contact with the second region 312. Note that the surface on which the first insulating layer 321 is formed serves as a light-receiving surface.

In FIG. 11A, both surfaces of the single crystal silicon substrate 300 have unevenness, which can be formed in such a manner that both the surfaces of the single crystal silicon substrate are subjected to etching without using masks in the etching for forming unevenness. In FIG. 11B, only one surface of the single crystal silicon substrate 300 has unevenness, which can be formed in such a manner that the other surface of the single crystal silicon substrate 300 is covered with a mask in the etching for forming unevenness and only the one surface is subjected to etching. The method described in Embodiment 1 can be referred to for the etching for forming the unevenness.

Incident light is reflected in a multiple manner on the surface processed to have unevenness, and travels obliquely in the single crystal silicon substrate; thus, the optical path length is increased. In addition, a so-called light trapping effect in which light reflected by a back electrode is totally reflected by the surface can occur.

The single crystal silicon substrate 300 has one conductivity type, and the first region 311 is a region having a conductivity type opposite to that of the single crystal silicon substrate 300. Thus, a p-n junction is formed at the interface between the single crystal silicon substrate 300 and the first region 311.

The second region 312 is a back surface field (BSF) layer, which has the same conductivity type as the single crystal silicon substrate 300 and has higher carrier density than the single crystal silicon substrate 300. In this embodiment, when the BSF layer is formed, an n-n⁺ junction or a p-p⁺ junction is formed, and minority carriers are repelled by the electric field of the n-n⁺ junction or the a p-p⁺ junction and attracted to the p-n junction side, whereby recombination of carriers in the vicinity of the second electrode 390 can be prevented.

Further, over the one surface of the single crystal silicon substrate 300, the first insulating layer 321 having a light-transmitting property is preferably provided. Provision of the insulating layer has a protection effect, an antireflection effect, and an effect of reducing surface defects of the single crystal silicon substrate 300. As the first insulating layer 321 having a light-transmitting property, a silicon oxide film or a silicon nitride film formed by a plasma CVD method or a sputtering method can be used. The surface defects of the single crystal silicon substrate 300 can be further reduced by the provision of the second insulating layer 322.

Each of the structures of the photoelectric conversion devices shown in FIGS. 11A and 11B is also referred to as a back contact type, in which an electrode is formed on one surface side of a substrate. Thus, a grid electrode and the like are not formed on the light-receiving surface side, so that a shadow loss is eliminated and conversion efficiency can be increased. In each of FIGS. 11A and 11B, the first region 311 on the p-n junction side is larger than the second region 312; however, the first region 311 and the second region 312 may have substantially the same size. Further, there is no limitation on the numbers of the first region 311 and the second region 312. The number of the first region 311 is not necessarily the same as that of the second region 312.

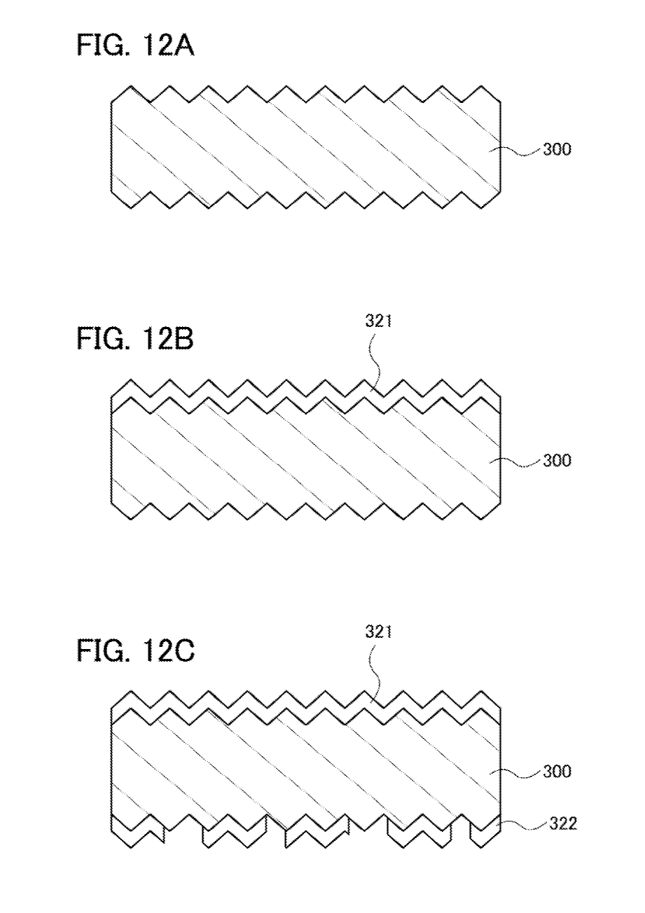

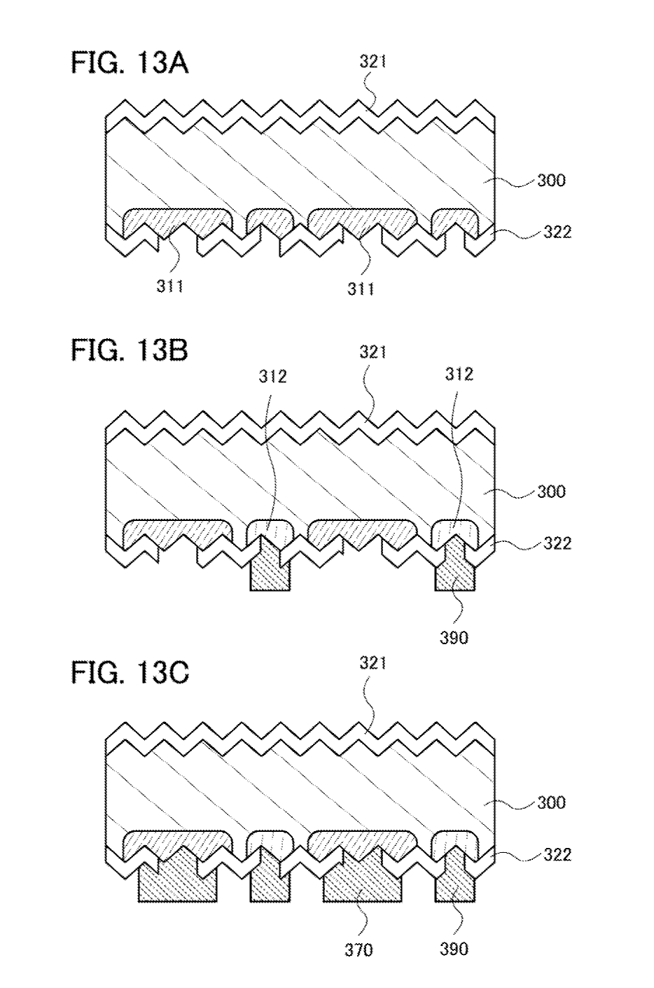

Next, a method for manufacturing the photoelectric conversion device shown in FIG. 11A is described with reference to FIGS. 12A to 12C and FIGS. 13A to 13C.

As the single crystal silicon substrate 300 used in one embodiment of the present invention, a single crystal silicon substrate having a (100) plane as a surface is used. The conductivity type and the manufacturing method of the single crystal silicon substrate are not limited and can be determined by the practitioner as appropriate. In this embodiment, an example in which a p-type single crystal silicon substrate is used as the single crystal silicon substrate 300 is described.

Next, the surface and the back surface of the single crystal silicon substrate 300 are processed to have unevenness (see FIG. 12A). Embodiment 1 can be referred to for the processing method for forming the unevenness.

Next, the first insulating layer 321 having a light-transmitting property is formed on the one surface of the single crystal silicon substrate 300 (see FIG. 12B). A silicon oxide film or a silicon nitride film with a thickness of greater than or equal to 50 nm and less than or equal to 100 nm, which is formed by a plasma CVD method or a sputtering method, can be used as the first insulating layer 321. In this embodiment, a silicon nitride film with a thickness of 50 nm formed by a plasma CVD method is used as the first insulating film 321.

Next, the second insulating layer 322 is formed on the other surface of the single crystal silicon substrate 300 (see FIG. 12C). A silicon oxide film or a silicon nitride film with a thickness of greater than or equal to 50 nm and less than or equal to 100 nm, which is formed by a plasma CVD method or a sputtering method, can be used as the second insulating layer 322. When such a film is used, an opening is provided in the second insulating layer 322 using a known processing technique. Alternatively, the second insulating layer 322 may be formed using a heat-resistant insulating resin by a screen printing method.

Next, the first region 311 is formed (see FIG. 13A). Here, the conductivity type of the single crystal silicon substrate 300 is p-type; thus, the first region 311 is formed to be a region having n-type conductivity. The first region 311 is thrilled in such a manner that impurities imparting n-type conductivity are diffused from the opening in the second insulating layer 322 formed on the other surface of the single crystal silicon substrate 300. As impurities imparting n-type conductivity, phosphorus, arsenic, antimony, and the like can be given. For example, the crystalline silicon substrate is subjected to heat treatment at a temperature higher than or equal to 800° C. and lower than or equal to 900° C. in an atmosphere of phosphorus oxychloride, whereby phosphorus can be diffused at a depth of approximately 0.5 μm from the surface of the single crystal silicon substrate. Note that the impurities imparting n-type conductivity are also diffused into the region where the second region 312 is to be formed.

Next, a material containing impurities imparting p-type conductivity is formed on the other surface of the single crystal silicon substrate 300 so as to cover the opening in the second insulating layer 322 reaching the region to be the second region 312, and the impurities are diffused to form a layer with a high carrier concentration, so that the n-type region is changed into the second region 312 which is p⁺ type. Through these steps, a p-p⁺ junction is formed. For example, an aluminum paste is formed so as to cover the opening reaching the region to be the second region 312 by a screen printing method and baking is performed to thermally diffuse aluminum into the region which has become the n-type region in the preceding step, so that the second region 312 and the second electrode 390 are formed.

Subsequently, a conductive resin is applied so as to cover the opening in the second insulating layer 322 reaching the region to be the first region 311 by a screen printing method, and baking is performed, so that the first electrode 370 is formed. Note that the conductive resin used here may be an aluminum paste, a silver paste, a copper paste, a nickel paste, a molybdenum paste, or the like. Further, the first electrode 370 may be a stacked layer of different materials, such as a stacked layer of a silver paste and a copper paste.

As described above, according to one embodiment of the present invention, a photoelectric conversion device having excellent electric characteristics can be formed.

This embodiment can be freely combined with any of the other embodiments and an example.

### EXAMPLE

In this example, optical characteristics and electric characteristics of a single crystal silicon substrate which has unevenness and was manufactured by the method described in Embodiment 1, and cell characteristics of a photoelectric conversion device which was manufactured using the single crystal silicon substrate are described.

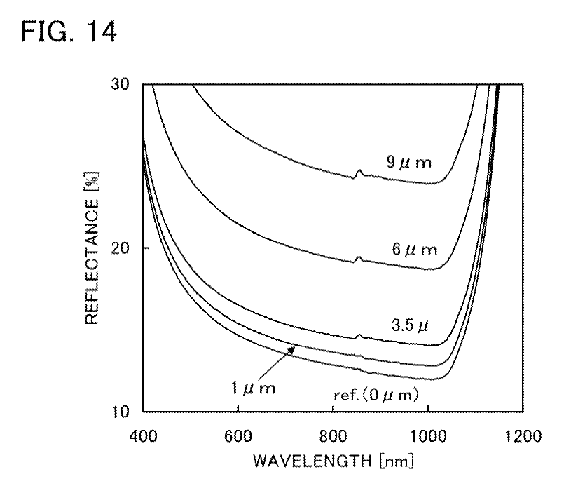

FIG. 14 shows measurement results of reflectance of samples in each of which unevenness was formed on a surface of the single crystal silicon substrate having a (100) plane as the surface by performing all the steps shown in FIG. 1 explained in Embodiment 1. The numeric value showing thickness in the figure denotes an etching amount using HF-nitric-acetic acid after the unevenness was formed using an alkaline solution. The reflectance increases as the etching amount increases with respect to the reference (0 μm). This suggests that, as described in Embodiment 1 with reference to FIGS. 2A and 2B or FIGS. 3A and 3B, the vertex angle of a projection becomes larger and a bottom of a depression has a curved surface as the etching amount increases. Note that it is found that difference in reflectance between the samples in each of which the etching amount of the single crystal silicon substrate was 3.5 μm or less and reference is extremely small.

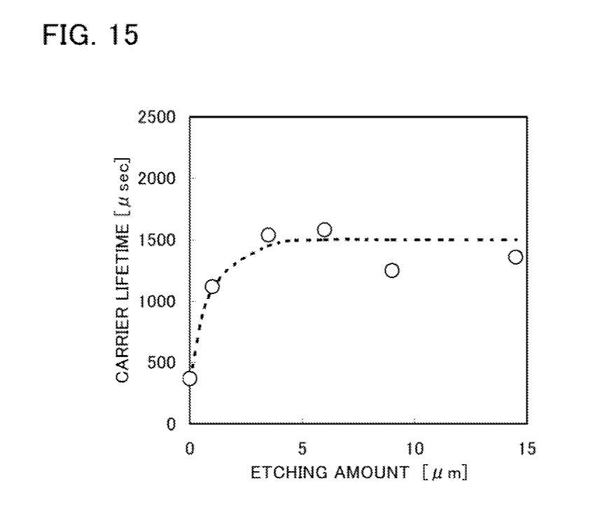

FIG. 15 shows measurement results of carrier lifetimes of samples manufactured under the same conditions as the samples used in the evaluation in FIG. 14. Note that in each of the samples, i-type amorphous silicon and p-type amorphous silicon were stacked on one surface of a single crystal silicon substrate having unevenness, and i-type amorphous silicon and n-type amorphous silicon were stacked on the other surface of the single crystal silicon substrate.

The results show that the carrier lifetime of the sample in which etching using HF-nitric-acetic acid was not performed is 500 μsec or less, whereas the carrier lifetimes of the samples in each of which the etching was performed to a depth of 1 μm or more is 1000 μsec or more. This shows that surface contamination and the absolute amount of surface defects are reduced by the etching using HF-nitric-acetic acid.

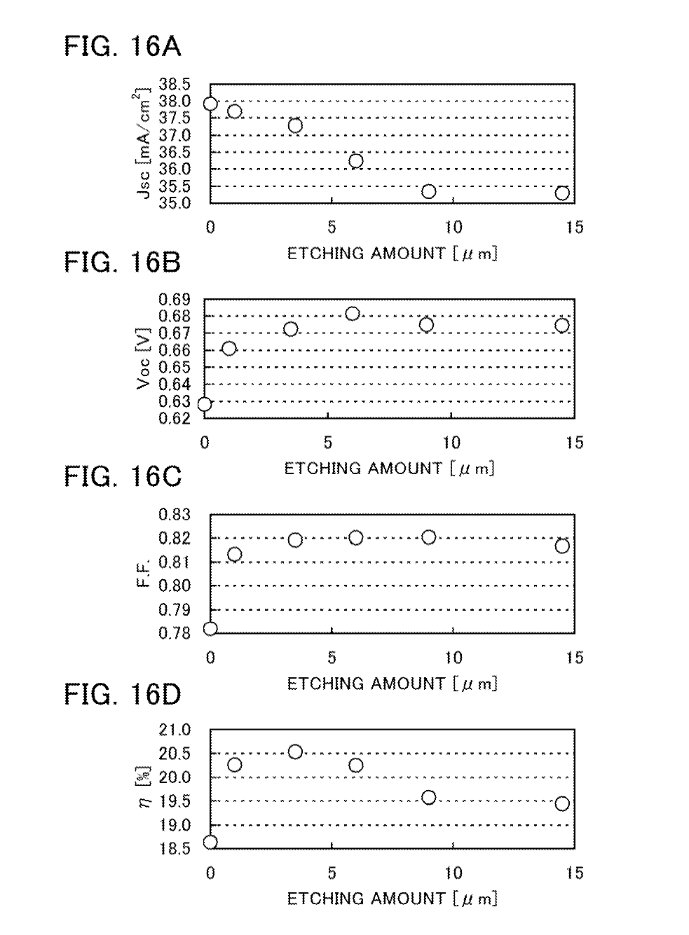

A photoelectric conversion device with a cell size of 125 mm×125 mm was manufactured by the method described in Embodiment 3 using a single crystal silicon substrate provided with unevenness under the same conditions as those described above, and I-V characteristics of the photoelectric conversion device were measured; FIGS. 16A to 16D show the results. Simulated solar radiation (a solar spectrum was AM 1.5, and irradiation intensity was 100 mW/cm²) generated by a solar simulator was used for the measurement.

FIG. 16A shows that the short circuit current density (Jsc) tends to decrease as the etching amount increases. This resulted from influences such as a decrease in optical path length in the single crystal silicon substrate due to the increase in the vertex angle of the projection by etching. Note that difference in the short circuit current density (Jsc) between the samples in each of which the etching amount of the single crystal silicon substrates is 3.5 μm or less and the reference (0 μm) is extremely small, which reflects the distribution of the reflectance in FIG. 14.

FIG. 16B shows that the open circuit voltage (Voc) tends to increase as the etching amount increases and tends to be saturated with an etching amount of 6 μm or more. Further, great improvement is made even in the case where the etching amount is small. This results from improvement in the carrier lifetime owing to effects of a reduction in surface area and the absolute amount of surface defects and improvement in coverage with a passivation film which resulted from the phenomenon in which the vertex angle of the projection becomes larger and the phenomenon in which the bottom of the depression has a curved surface, and an effect of a reduction in metal contamination by the etching using HF-nitric-acetic acid.

FIG. 16C shows that a fill factor (F.F.) improves in a manner similar to that of the open circuit voltage (Voc). The reason for the improvement is similar to that for the improvement in the open circuit voltage (Voc).

FIG. 16D shows that the conversion efficiency (η) has a result obtained by the combination of the above results. The conversion efficiency (η) with an etching amount of 3.5 μm is the best result. That is, when the etching amount is 3.5 μm or less, all or any one of the following is not sufficiently achieved: a reduction in the absolute amount of surface defects, removal of contaminants, and coverage with the passivation film, which means that a factor in reducing electric characteristics is not removed. Further, when the etching amount is larger than 3.5 μm, a reduction in the absolute amount of surface defects, removal of contaminants, and coverage with the passivation film are all sufficiently achieved; however, a large reduction in the short circuit current density (Jsc) due to the decrease in the number of unevennesses causes a reduction in conversion efficiency.

The above results show that one embodiment of the present invention contributes to improvement in the conversion efficiency of the photoelectric conversion device.

This example can be freely combined with any of the embodiments.

This application is based on Japanese Patent Application serial no. 2011-102573 filed with Japan Patent Office on Apr. 29, 2011, the entire contents of which are hereby incorporated by reference.

What is claimed is:

1. A photoelectric conversion device comprising:
a pair of electrode;
a single crystal silicon substrate having a first conductivity type;
a first region on a first surface of the single crystal silicon substrate, the first region having a second conductivity type opposite to the first conductivity type;
an insulating film on the first region; and
a second region on a second surface of the single crystal silicon substrate, the second region having the first conductivity type and having higher carrier density than the single crystal silicon substrate,
wherein at least the first surface of the single crystal silicon substrate has unevenness including a plurality of minute projections and depressions formed between adjacent projections, and
wherein at a cross section of one of the projections, a vertex of the one of the projections forms an obtuse angle, and a bottom of an adjacent depression has a curved surface.

2. The photoelectric conversion device according to claim 1, wherein an angle of the vertex is 90° or more and 120° or less.

3. The photoelectric conversion device according to claim 1, wherein each of the projections has a substantially square pyramidal shape.

4. The photoelectric conversion device according to claim 1, wherein the cross section divides each of a first side surface and a second side surface facing the first side surface of the one of the projections into two equal parts through the vertex of the one of the projections.

5. A photoelectric conversion device comprising:
a pair of electrodes,
a single crystal silicon substrate having a first conductivity type;
a first silicon semiconductor layer being in contact with a first surface of the single crystal silicon substrate;
a second silicon semiconductor layer being in contact with the first silicon semiconductor layer and having a second conductivity type opposite to the first conductivity type;
a third silicon semiconductor layer being in contact with a second surface of the single crystal silicon substrate; and
a fourth silicon semiconductor layer being in contact with the third silicon semiconductor layer, the fourth silicon semiconductor layer having the first conductivity type and having higher carrier density than the single crystal silicon substrate,
wherein at least the first surface of the single crystal silicon substrate has unevenness including a plurality of minute projections and depressions formed between adjacent projections, and
wherein at a cross section of one of the projections, a vertex of the one of the projections forms an obtuse angle, and a bottom of an adjacent depression has a curved surface.

6. The photoelectric conversion device according to claim 5, wherein each of the first silicon semiconductor layer and the third silicon semiconductor layer comprises amorphous silicon having i-type conductivity.

7. The photoelectric conversion device according to claim 5, wherein each of the second silicon semiconductor layer and the fourth silicon semiconductor layer comprises one of amorphous silicon and microcrystalline silicon.

8. The photoelectric conversion device according to claim 5, wherein an angle of the vertex is 90° or more and 120° or less.

9. The photoelectric conversion device according to claim 5, wherein each of the projections has a substantially square pyramidal shape.

10. The photoelectric conversion device according to claim 5, wherein the cross section divides each of a first side surface and a second side surface facing the first side surface of the one of the projections into two equal-parts through the vertex of the one of the projections.

11. A photoelectric conversion device comprising:
a single crystal silicon substrate having a first conductivity type;
a first insulating layer on a first surface of the single crystal silicon substrate;
a first region having a second conductivity type opposite to the first conductivity type;
a second region having the first conductivity type and having higher carrier density than the single crystal silicon substrate, the first region and the second region being provided in a second surface of the single crystal silicon substrate;
a second insulating layer on the second surface of the single crystal silicon substrate;
a first electrode being in contact with the first region and provided on the second insulating layer; and
a second electrode being in contact with the second region and provided on the second insulating layer,
wherein at least the first surface of the single crystal silicon substrate has unevenness including a plurality of minute projections and depressions formed between adjacent projections, and
wherein at a cross section of one of the projections, a vertex of the one of the projections forms an obtuse angle, and a bottom of an adjacent depression has a curved surface.

12. The photoelectric conversion device according to claim 11, wherein an angle of the vertex is 90° or more and 120° or less.

13. The photoelectric conversion device according to claim 11, wherein each of the projections has a substantially square pyramidal shape.

14. The photoelectric conversion device according to claim 11, wherein the cross section divides each of a first side surface and a second side surface facing the first side surface of the one of the projections into two equal parts through the vertex of the one of the projections.

15. A method for manufacturing a photoelectric conversion device comprising the steps of:
soaking a surface of a single crystal silicon substrate in an alkaline solution to perform etching so that unevenness including a plurality of minute projections and depressions formed between adjacent projections are formed, wherein the surface has a (100) plane;
soaking the single crystal silicon substrate having the unevenness in a mixed acid solution to perform etching so that at a cross section of one of the projections, a vertex of one of the projections forms an obtuse angle, and a bottom of an adjacent depression has a curved surface.

16. The method for manufacturing a photoelectric conversion device according to claim 15, wherein the alkaline solution is a solution containing potassium hydroxide or sodium hydroxide.

17. The method for manufacturing a photoelectric conversion device according to claim 15, wherein the mixed acid solution contains hydrofluoric acid, nitric acid, and acetic acid.

18. The method for manufacturing a photoelectric conversion device according to claim 15, wherein an angle of the vertex is 90° or more and 120° or less.

19. The method for manufacturing a photoelectric conversion device according to claim 15, wherein each of the projections has a substantially square pyramidal shape.

20. The method for manufacturing a photoelectric conversion device according to claim 15, wherein the cross section divides each of a first side surface and a second side surface facing the first side surface of the one of the projections into two equal parts through the vertex of the one of the projections.
